(19) United States
(12) Patent Application Publication
(10) Pub. No.: US 2025/0331257 A1
(43) Pub. Date: Oct. 23, 2025

(54) JFET DEVICE WITH IMPROVED DYNAMIC CHARACTERISTICS

(71) Applicant: SEMICONDUCTOR COMPONENTS INDUSTRIES, LLC, Scottsdale, AZ (US)

(72) Inventor: Alexander Viktorovich BOLOTNIKOV, Niskayuna, NY (US)

(73) Assignee: SEMICONDUCTOR COMPONENTS INDUSTRIES, LLC, Scottsdale, AZ (US)

(21) Appl. No.: 18/814,370

(22) Filed: Aug. 23, 2024

Related U.S. Application Data
(60) Provisional application No. 63/634,986, filed on Apr. 17, 2024.

(51) Int. Cl. H01L 29/10; H01L 29/06; H01L 29/16; H01L 29/808; H03K 17/687

(52) U.S. Cl. CPC H10D 62/343; H10D 30/831; H10D 62/126; H10D 62/8325; H03K 17/6871

(57) ABSTRACT

A power switch is disclosed. The power switch includes a metal-oxide semiconductor field-effect transistor (MOSFET) and a junction field effect transistor (JFET). The JFET is arranged in a cascode configuration with the MOSFET. The JFET includes a first plurality of JFET cells having a first gate resistance and a second plurality of JFET cells having a second gate resistance, wherein the second gate resistance is greater than the first gate resistance.

This application claims the benefit of provisional patent application No. 63/634,986, filed Apr. 17, 2024, which is hereby incorporated by reference herein in its entirety.

### TECHNICAL FIELD

The disclosure relates generally to junction field-effect transistors (JFETs), and particularly to techniques for improving dynamic characteristics of JFETs.

### BACKGROUND

JFETs may be used in power electronics, such as switching power converters and inverters. In some applications, a high-voltage rated power switch may be formed by utilizing a high-voltage normally-on JFET in a cascode configuration with a lower-voltage metal-oxide semiconductor field-effect transistor (MOSFET). Such power switches may be required to switch inductive loads at high switching frequencies. Thus, such power switches may be subject to voltage overshoots, which can lead to ringing and potential parasitic turn-on and/or avalanche failure if the overshoot exceeds the maximum voltage rating of the power switch. The inventor of embodiments of the present disclosure has recognized that placing resistance in the gate path of the MOSFET may slow turn-on and turn-off speeds and reduce voltage overshoot. The inventor of embodiments of the present disclosure has also recognized that resistance in the gate path of the MOSFET may negatively affect switching loss associated with switching the power switch on and off. Embodiments of the present disclosure may address one or more of these challenges.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1A illustrates a schematic diagram of a system including a power switch coupled to a load in accordance with embodiments of the present disclosure.

FIG. 1B illustrates plot diagrams showing switching waveforms of a power switch in accordance with embodiments of the present disclosure.

FIG. 1C illustrates plot diagrams showing switching waveforms of a power switch in accordance with embodiments of the present disclosure.

FIG. 2A illustrates a top layout view of a plurality of JFET cells in accordance with embodiments of the present disclosure.

FIG. 2B illustrates a cross-section view of a JFET cell in accordance with embodiments of the present disclosure.

FIG. 2C illustrates a cross-section view of a JFET cell in accordance with embodiments of the present disclosure.

FIG. 2D illustrates a top layout view of a first and a second plurality of JFET cells in accordance with embodiments of the present disclosure.

FIG. 3 illustrates a top layout view of a first and a second plurality of JFET cells in accordance with embodiments of the present disclosure.

FIG. 4A illustrates a cross-section view of a trench JFET cell in accordance with embodiments of the present disclosure.

FIG. 4B illustrates a cross-section view of a planar vertical channel JFET cell in accordance with embodiments of the present disclosure.

FIG. 4C illustrates a top layout view of JFET cells in accordance with embodiments of the present disclosure.

FIGS. 5A-5E illustrate portions of top layout views of multiple JFET cell patterns in accordance with embodiments of the present disclosure.

FIG. 6 illustrates a top layout view of a JFET including a first and a second plurality of JFET cells in accordance with embodiments of the present disclosure.

### DETAILED DESCRIPTION

Details of one or more embodiments are set forth in the description below and the accompanying drawings. Other features will be apparent from the description, drawings, and from the claims.

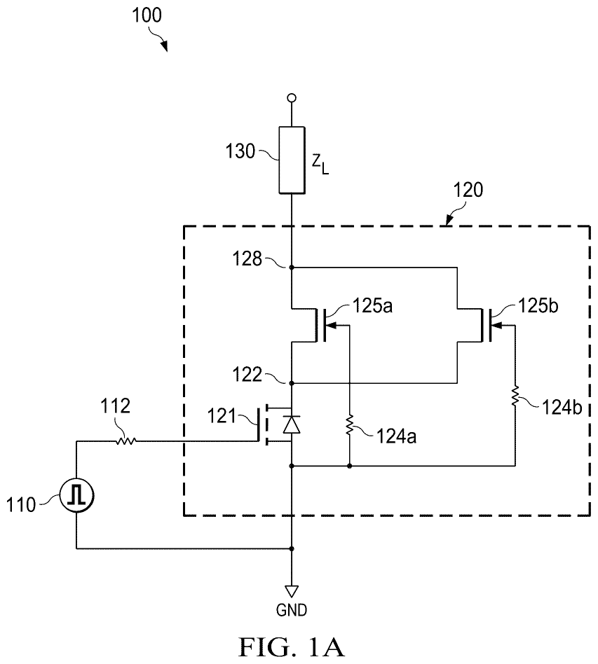

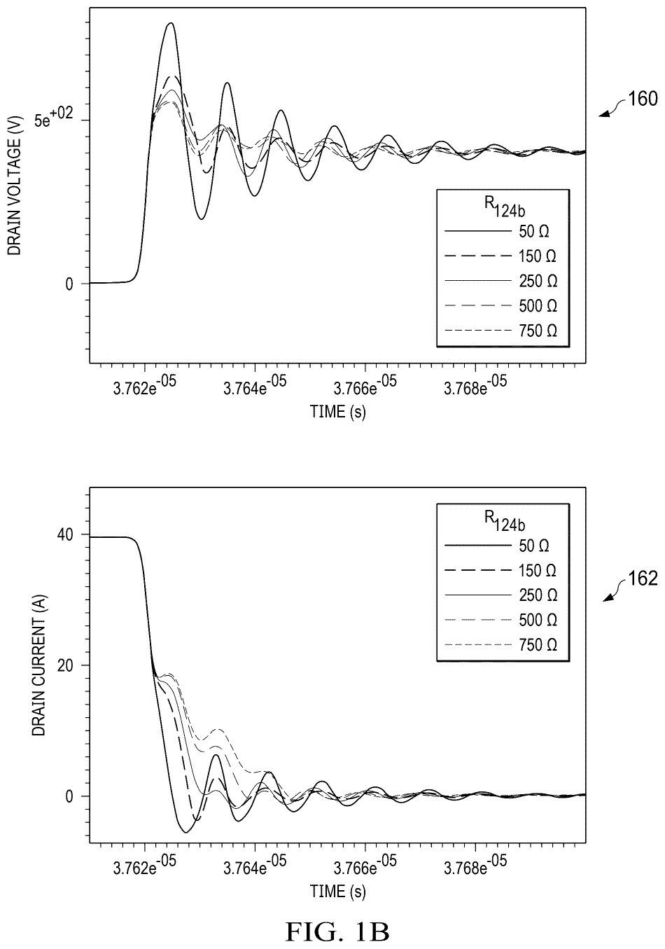

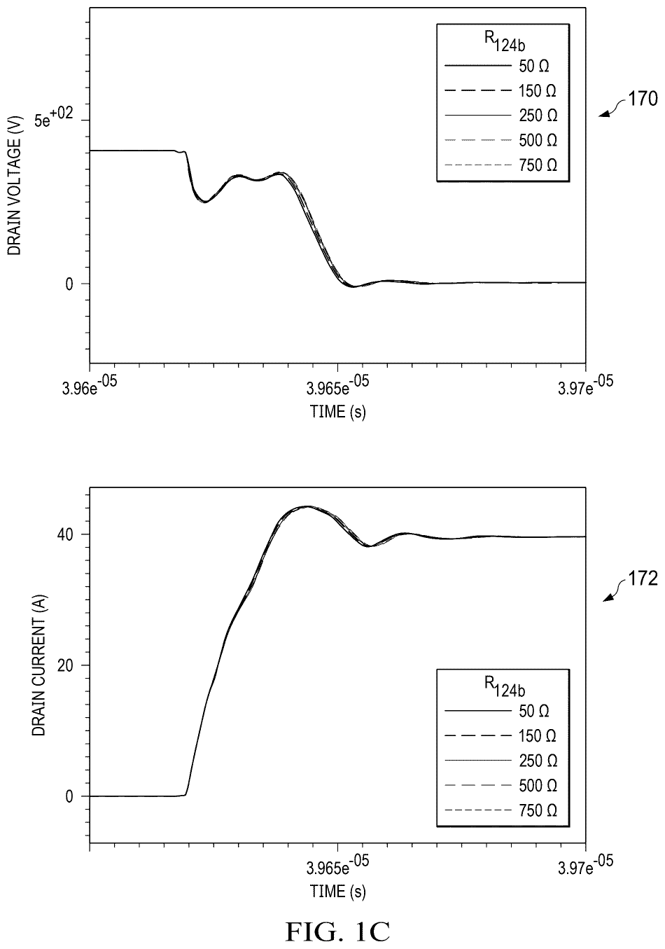

FIG. 1A illustrates a schematic diagram of system 100 including power switch 120 coupled to load 130 in accordance with embodiments of the present disclosure. Power switch 120 may include MOSFET 121, first gate resistance 124a, second gate resistance 124b, and a JFET collectively formed by JFET cell 125a, and JFET cell 125b. Power switch 120 may receive a switching signal from gate driver 110. For example, gate driver 110 may be coupled, via resistor 112, to the gate of MOSFET 121. Gate driver 110 may turn power switch 120 on and off repeatedly by applying a repeating high and low switching signal (e.g., voltage) to the gate of MOSFET 121. Power switch 120 may be coupled to load 130, which may be coupled via terminal 128 to the drains of JFET cells 125a and 125b. In some embodiments, load 130 may be inductive. Thus, power switch 120 may incur voltage overshoots at terminal 128 when turning off. As described in further detail below, JFET cells 125a and 125b, as well as their respective first gate resistance 124a and second gate resistance 124b, may be configured to limit voltage overshoots at terminal 128 while also limiting switching loss associated with switching on and off power switch 120.

As shown in FIG. 1A, JFET cell 125a and JFET cell 125b may be used in a cascode configuration with MOSFET 121, with the sources of JFET cells 125a and 125b coupled to the drain of MOSFET 121 at node 122. JFET cells 125a and 125b may be rated at high voltage levels, such as 40 V, 80 V, 120 V, 200 V, 500 V, 800 V, or more. In some embodiments, MOSFET 121 may be rated at a voltage lower than that of JFET cells 125a and 125b. MOSFET 121 may be rated at, for example, 30 V.

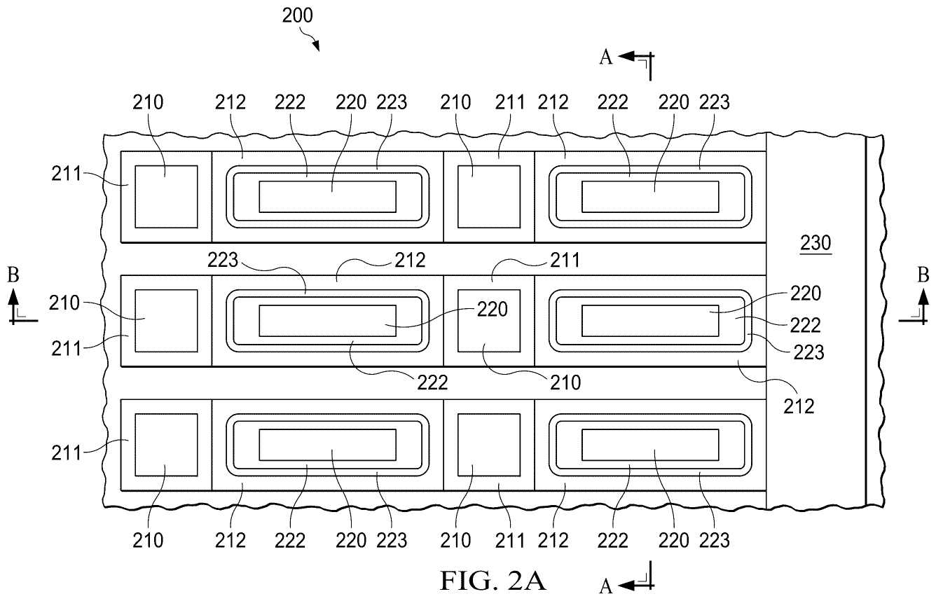

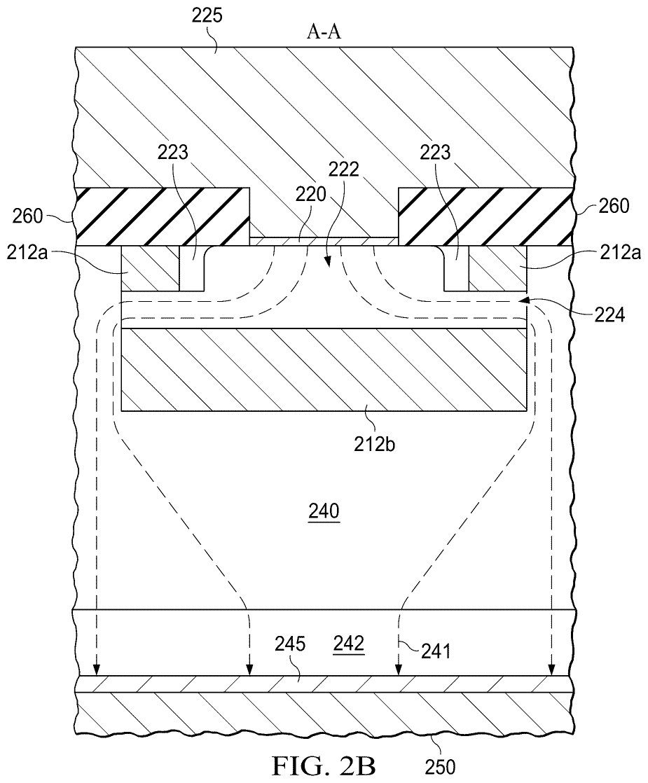

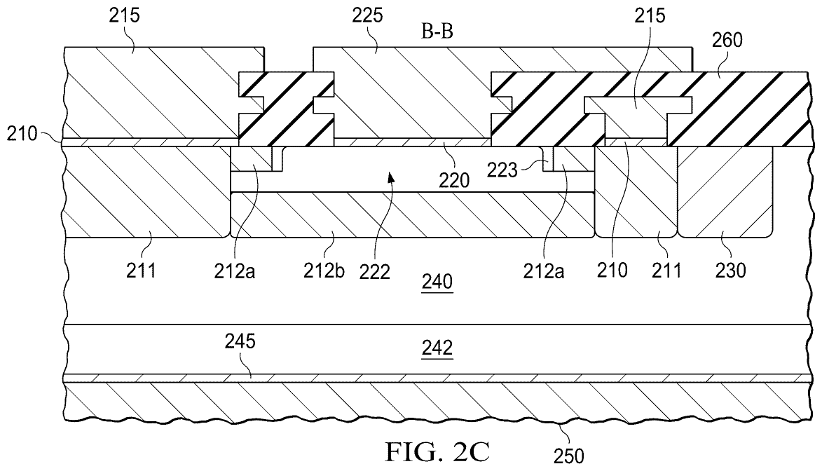

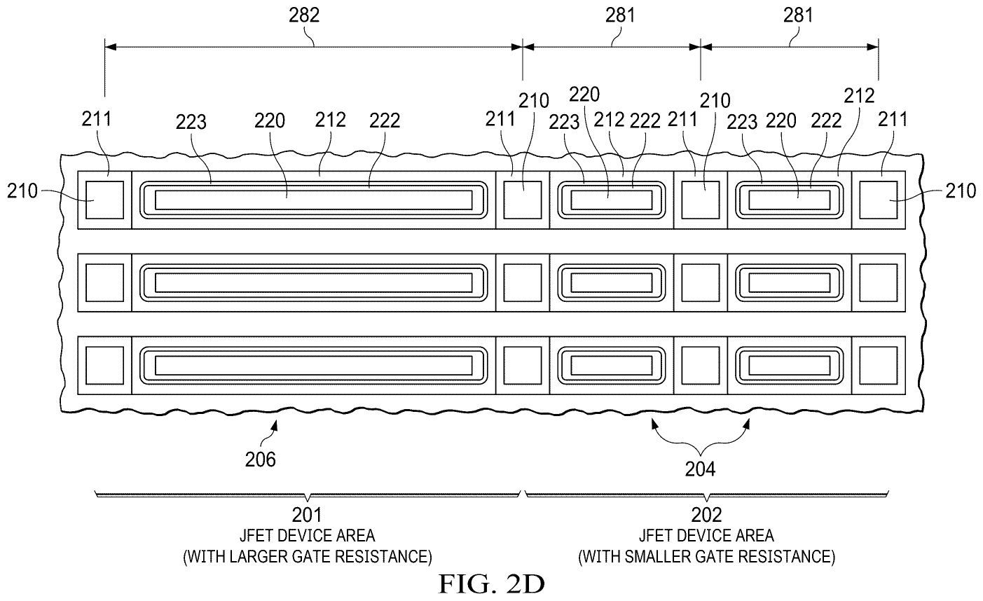

As described in further detail below, JFET cells 125a and 125b may represent different cells of a single JFET structure. As also described in further detail below, each of JFET cells 125a and 125b may represent multiple individual cells. For example, JFET cell 125a may represent a first plurality of JFET cells (such as the first plurality of JFET cells 204 in FIG. 2D) collectively having a first gate resistance 124a, and JFET cell 125b may represent a second plurality of JFET cells (such as the second plurality of JFET cells 206 in FIG. 2D) collectively having a second gate resistance 124b. In some embodiments, JFET cells 125a and 125b may be formed together on a single integrated circuit die with their respective sources coupled together and their respective drains coupled together. JFET cells 125a and 125b may form a normally-on JFET device. For example, when paired with a low-side N-channel MOSFET such as MOSFET 121, JFET cells 125a and 125b may have their gates coupled to ground via first and second gate resistances 124a and 124b respectively.

In some embodiments, MOSFET 121 may be monolithically formed on the same semiconductor substrate as the JFET formed by JFET cells 125a and 125b. For example, MOSFET 121 and JFET cells 125a and 125b may be silicon devices formed on a silicon substrate, silicon-carbide (SiC) devices formed on a SiC substrate, or gallium arsenide (“GaN”) devices formed on a GaN substrate. MOSFET 121 and JFET cells 125a and 125b may also be formed on any other suitable semiconductor substrate. In other embodiments, MOSFET 121 may be formed on a first semiconductor die and the JFET formed by JFET cell 125a and JFET cell 125b may be monolithically formed on a second semiconductor die. For example, MOSFET 121 may be a silicon n-channel MOSFET be formed on a first die with a silicon substrate, and the JFET formed by JFET cells 125a and 125b may be monolithically formed on a second semiconductor die with a silicon-carbide (SiC) substrate. In such embodiments where MOSFET 121 is formed on a different semiconductor die than the JFET formed by JFET cells 125a and 125b, MOSFET 121 and the JFET formed by JFET cells 125a and 125b may be co-packaged together in a single multi-die integrated circuit package.

To improve the dynamic switching characteristics of power switch 120, JFET cell 125a and JFET cell 125b may be implemented with different values for first gate resistance 124a and second gate resistance 124b. JFET cell 125a may be configured as a fast cell with a low-value first gate resistance 124a while JFET cell 125b may be configured as a slow cell with a high-value second gate resistance 124b. By providing different JFET cells with different gate resistances, the transient turn-off time of power switch 120 as a whole can be slowed, thus reducing voltage overshoot and ringing that may occur at terminal 128 when switching off power switch 120. The relative resistance values of first and second gate resistances 124a and 124b, as well as the relative areas of JFET cells 125a and 125b, may be configured to reduce voltage peaks at terminal 128, while limiting or avoiding any negative impact additional gate resistance may have on a turn-on time of the power switch 120.

In some embodiments, the resistance value of second gate resistance 124b may be greater than that of first gate resistance 124a by a ratio of 10:1, 20:1, 50:1, 100:1, 200:1, 500:1, 700:1 or more. First gate resistance 124a may have a resistance value of, for example, 2 Ohms, 1 Ohm, 0.5 Ohms, or less. Meanwhile, second gate resistance 124b may have a resistance value of, for example, 10 Ohms, 20 Ohms, 50 Ohms, 100 Ohms, 150 Ohms, 200 Ohms, 250 Ohms, 500 Ohms, 750 Ohms, or more.

In some embodiments, the area of JFET cell 125a may be equal to or greater than that of JFET cell 125b to prevent the slower JFET cell 125b from negatively impacting the turn-on time of power switch 120. Although JFET cell 125a and JFET cell 125b may be referred to herein as JFET cells, each of JFET cell 125a and JFET cell 125b may represent a plurality of similarly configured cells. JFET cell 125a may represent a plurality of fast JFET cells configured with a low gate resistance value, and JFET cell 125b may represent a plurality of slow JFET cells configured with a high gate resistance value. The individual cells that form JFET cell 125a may be configured to have a total area that is greater than that of the individual cells that form JFET cell 125b. Accordingly, JFET cell 125a may predominate during the turn-on of power switch 120, thus limiting or avoiding any negative impact that the larger gate resistance of JFET cell 125b may have on the transient turn-on time of power switch 120. In some embodiments, JFET cell 125a may have a total area that is equal to or greater than that of JFET cell 125b by a ratio of, for example, 1:1, 2:1, 4:1, 6:1, 8:1, 10:1, 12:1, 14:1, 16:1, 18:1, 20:1 or more.

FIGS. 1B and 1C illustrate plot diagrams showing switching waveforms of power switch 120 in accordance with embodiments of the present disclosure. Specifically, FIGS. 1B and 1C respectively illustrate the turn-off and turn-on transitions of an example embodiment of power switch 120 across different resistance values for second gate resistance 124b (R_{124b}) with a resistance value for first gate resistance 124a at 1.1 Ohm, resistor 112 set to 8.2 Ohms, an internal gate resistance for MOSFET 121 at an additional 1.0 Ohm, and with the total area of JFET cell 125a being greater than the total area of JFET cell 125b by a ratio of 10:1. As shown by plot 160 in FIG. 1B, the overshoot of the drain voltage (i.e., the voltage at terminal 128 of power switch 120) during the turn-off transition may decrease as R_{124b} increases across a range of values, for example, from 50 Ohms to 750 Ohms. Likewise, as shown by plot 162 in FIG. 1B, the drain current (i.e., the current at terminal 128 of power switch 120) during the turn-off transition may settle more evenly as the R_{124b} increases across a range of values, for example, from 50 Ohms to 750 Ohms.

Further, as shown by plot 170 and plot 172 in FIG. 1C, the turn-on transition of the drain voltage and drain current may be only nominally affected by the different values of R_{124b} ranging from, for example, 50 Ohms to 750 Ohms. As described above, setting the total area of JFET cell 125a to be larger than JFET cell 125b, at the 10:1 ratio used to generate the plots in FIGS. 1B and 1C for example, may limit or avoid any negative impact that the larger gate resistance of JFET cell 125b may have on the turn-on transition of power switch 120.

First and second gate resistances 124a and 124b may be implemented in any suitable manner. In some embodiments, first gate resistance 124a may include the parasitic resistance of the gate path coupling the gate of JFET cell 125a to ground GND. First gate resistance 124a may include for example, the resistance of the semiconductor gate region of JFET cell 125a and the resistance between the gate contacts of JFET cell 125a and ground GND. Second gate resistance 124b may likewise include the resistance of the semiconductor gate region of JFET cell 125b and the resistance between the gate contacts of JFET cell 125b and ground GND. In some embodiments, second gate resistance 124b may also include one or more additional resistors, either integrated or discrete, placed in the path between the gate of JFET cell 125b and ground GND.

As described below with reference to FIG. 2A through FIG. 6, the layout of fast JFET cells, such as JFET cell 125a, and slow JFET cells, such as JFET cell 125b, may be configured in a manner to tune the associated gate resistances of the slow and fast cells to desired resistance levels.

FIG. 2A illustrates a top layout view of a plurality of JFET cells 200 in accordance with embodiments of the present disclosure. FIG. 2B and FIG. 2C illustrate cross-section layout views of a JFET cell in accordance with embodiments of the present disclosure. Specifically, FIG. 2B illustrates a cross-section view of one of the plurality of JFET cells 200 from FIG. 2A along cutline “A-A,” and FIG. 2C illustrates a cross-section view of one of the plurality of JFET cells 200 from FIG. 2A along cutline “B-B.”

The plurality of JFET cells 200 shown in FIG. 2A, and represented in FIGS. 2B and 2C, may include lateral channel regions. For the purposes of the present disclosure, a JFET including JFET cells with lateral channel regions may be referred to as a lateral JFET. As described below, different groups of lateral JFET cells may be provided with different dimensions to provide different gate-region resistance values, thereby providing different groups of JFET cells with different overall gate resistances. For example, different groupings of lateral JFET cells may be configured with dimensions such that a first plurality of JFET cells have a first gate resistance, and a second plurality of JFET cells have a second gate resistance, wherein the second gate resistance of the second plurality of JFET cells is greater than the first gate resistance of the first plurality of JFET cells by a ratio of 10:1 or more.

As collectively shown in FIG. 2A and in the A-A cross section view of FIG. 2B, each of the plurality of JFET cells 200 may include a source region 222 coupled to a source terminal 225 via source contact 220, a low-doped region 223 extending from the sides of the source region 222, a channel region 224, and a drift region 240 coupled to a drain terminal 250 via substrate 242 and drain contact 245. Each of source region 222, channel region 224, and drift region 240 may be formed with a first conductivity type. For example, in embodiments where substrate 242 is an n-type substrate, each of the source region 222, channel region 224, and drift region 240 may be n-type regions. As another example, in embodiments where substrate 242 is a p-type substrate, each of source region 222, channel region 224, and drift region 240 may be p-type regions.

As also shown in the A-A cross section view of FIG. 2B and the B-B cross section view of FIG. 2C, each of the plurality of JFET cells 200 may also include one or more gate regions 212 of a second conductivity type. For example, each JFET cell may include upper gate region 212a above channel region 224. Dielectric 260 may be located above upper gate region 212a and may electrically isolate upper gate region 212a from source terminal 225. Each JFET cell may also include lower gate region 212b below source region 222 and channel region 224. As shown in the A-A cross section view of FIG. 2B, channel region 224 may extend laterally between upper gate region 212a and lower gate region 212b. A voltage potential applied to upper gate region 212a and lower gate region 212b may serve to pinch channel region 224, thus varying the conductivity of the JFET cell from drain to source. Thus, electric current 241 through the JFET cell may be controlled by the voltage potential applied to upper gate region 212a and lower gate region 212b. The second conductivity type of upper gate region 212a and lower gate region 212b may be opposite to the first conductivity type. For example, in embodiments where source region 222, channel region 224, and drift region 240 are n-type regions, upper gate region 212a and lower gate region 212b may be p-type regions. And in embodiments where source region 222, channel region 224, and drift region 240 are p-type regions, upper gate region 212a and lower gate region 212b may be n-type regions.

As also shown in the B-B cross section of FIG. 2C, upper gate region 212a and lower gate region 212b may be coupled to gate terminal 215 via gate contact region 211 and gate contact 210. Gate region 212 (including upper gate region 212a and lower gate region 212b) and gate contact region 211 may have associated resistances that contribute to the overall gate resistance of the respective JFET cell. The doping profile of gate region 212 and gate contact region 211 may affect the gate resistance. For example, heavier doping may provide a smaller gate resistance, and lighter doping may provide a larger resistance. In some embodiments, gate contact region 211 may be more heavily doped than gate region 212 (including upper gate region 212a and lower gate region 212b). The effective distance from gate contact 210 to the most remote point of the upper gate region 212a and the most remote point of the lower gate region 212b may also contribute to the gate resistance of the JFET cell. For example, the lateral distance from gate contact 210 to the most remote point of the upper gate region 212a and the most remote point of the lower gate region 212b may affect the gate resistance, with a longer distance contributing to a larger gate resistance and a shorter distance contributing to a smaller gate resistance. Thus, as described below with reference to FIG. 2D, the gate resistance of different JFET cells may be varied across different cells by varying the cell length of the JFET cell between respective gate contacts on opposing sides of a JFET cell.

As shown in FIGS. 2A and 2C, a termination region 230 of a second conductivity type may be located adjacent to the active area in which the plurality of JFET cells 200 is formed. It will be appreciated that FIG. 2A is a partial view of termination region 230 and the active area in which a plurality of JFET cells (including the plurality of JFET cells 200) is formed. In some embodiments, termination region 230 may surround a plurality of JFET cells (including the plurality of JFET cells 200). For example, termination region 230 may define an outer perimeter of the active area in which a plurality of JFET cells (including the plurality of JFET cells 200) is formed. In some embodiments, termination region 230 may include one or more doped regions, formed for example by diffusion or implantation, and/or one or more trench structures to reduce gradients in the electric field at geometrical sharp points associated with operation of the device at high voltages. Thus, termination region 230 may help maintain the breakdown voltage (BV) of the JFET cells close to a maximum BV as limited by material properties. For example, termination region 230 may prevent breakdown from occurring below a blocking entitlement of the plurality of JFET cells 200, e.g., by terminating high electric fields during off-state operation.

The second conductivity type of termination region 230 may be opposite to the first conductivity type. For example, in embodiments where source region 222, channel region 224, and drift region 240 are n-type regions, termination region 230 may be a p-type region. And in embodiments where source region 222, channel region 224, and drift region 240 are p-type regions, termination region 230 may be an n-type region.

FIG. 2D illustrates a top layout view of a first plurality of JFET cells 204 and a second plurality of JFET cells 206 in accordance with embodiments of the present disclosure. The first plurality of JFET cells 204 and the second plurality of JFET cells 206 in FIG. 2D may be lateral JFET cells and may include lateral channel regions similar to those of FIGS. 2A-2C. The first plurality of JFET cells 204 may collectively represent an embodiment of JFET cell 125a of FIG. 1A having a first gate resistance 124a, while the second plurality of JFET cells 206 may collectively represent an embodiment of JFET cell 125b of FIG. 1A having a second gate resistance 124b. In some embodiments, the first plurality of JFET cells 204 and the second plurality of JFET cells 206 may be monolithically formed together on a semiconductor die, for example a semiconductor die with a silicon-carbide (SiC) substrate.

In some embodiments, different JFET cells from among the first plurality of JFET cells 204 and the second plurality of JFET cells 206 may have different cell lengths between gate contacts 210 on opposing ends of the respective JFET cells. For example, as shown in FIG. 2D, the first plurality of JFET cells 204 may each have a first cell length 281 while the second plurality of JFET cells 206 may each have a second cell length 282, wherein the second cell length 282 of the second plurality of JFET cell 206 may be greater than the first cell length 281 of the first plurality of JFET cells 204. Specifically, the second plurality of JFET cells 206 in JFET device area 201 may have a longer distance between gate contacts as compared to the first plurality of JFET cells 204 in JFET device area 202. Accordingly, the distance between a gate contact 210 and the most remote point of the gate region 212 surrounding the source region 222 may be greater for the second plurality of JFET cells 206 within JFET device area 201 as compared to the first plurality of JFET cells 204 within JFET device area 202. Accordingly, due to the different resistances of the different respective gate regions 212, the second plurality of JFET cells 206 may have a second gate resistance that is greater than a first gate resistance of the first plurality of JFET cells 204.

Although FIG. 2D illustrates JFET device area 201 as having a larger area than JFET device area 202, further portions of a JFET device including the first plurality of JFET cells 204 and the second plurality of JFET cells 206 may include further cells with the same spacing as the first plurality of JFET cells 204 within JFET device area 202. As described above with reference to FIG. 1A, the total area of JFET cells having the smaller gate resistance may be equal to or greater than the total area of JFET cells having a larger gate resistance. For example, the first area of a first plurality of smaller-gate-resistance JFET cells, such as the first plurality of JFET cells 204, may be equal to or greater than a second area of a second plurality of larger-gate resistance JFET cells, such as the second plurality of JFET cells 206, by a ratio ranging from 1:1 to 20:1 or more.

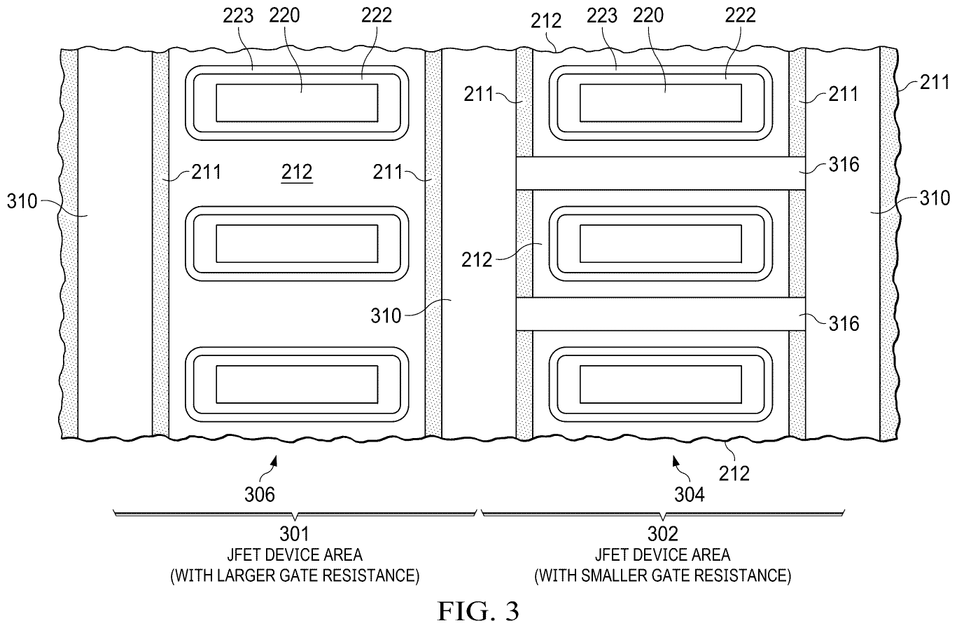

FIG. 3 illustrates a top layout view of a first plurality of JFET cells 304 and a second plurality of JFET cells 306 in accordance with embodiments of the present disclosure. The first plurality of JFET cells 304 may collectively represent an embodiment of JFET cell 125a of FIG. 1A having a first gate resistance 124a, while the second plurality of JFET cells 306 may collectively represent an embodiment of JFET cell 125b of FIG. 1A having a second gate resistance 124b. In some embodiments, the first plurality of JFET cells 304 and the second plurality of JFET cells 306 may be monolithically formed together on a semiconductor die, for example a semiconductor die with a silicon-carbide (SiC) substrate. The first plurality of JFET cells 304 and the second plurality of JFET cells 306 in FIG. 3 may be lateral JFET cells and may include lateral channel regions similar to the JFET cells illustrated in FIGS. 2A-2D.

In some embodiments, a JFET formed, at least in part, by the first plurality of JFET cells 304 and the second plurality of JFET cells 306 may further include gate contact strips 310 positioned along short edges of each of the first plurality of JFET cells 304 and each of the second plurality of JFET cells 306. For example, as shown in FIG. 3, a second plurality of JFET cells 306 in JFET device area 301, and a first plurality of JFET cells 304 and in JFET device area 302, may include gate contact strips 310 positioned along short edges of the respective individual JFET cells from among the first plurality of JFET cells 304 and the second plurality of JFET cells 306. As shown in FIG. 3, an instance of gate contact strip 310 may be located between the first plurality of JFET cells 304 and the second plurality of JFET cells 306. Thus, as shown in FIG. 3, as single instance of gate contact strip 310 may serve as one of the first and second gate contact strips positioned along short edges of individual cells within the first plurality of JFET cells 304, as well as one of the first and second gate contact strips positioned along short edges of individual cells within the second plurality of JFET cells 306. For the purposes of the present disclosure, the short edges of the JFET cells may refer to the shorter edges of rectangular-shaped JFET cells, such as those shown in FIG. 3, and the long edges of the JFET cells may refer to the longer edges of the rectangular-shaped JFET cells.

In some embodiments, a JFET formed, at least in part, by the first plurality of JFET cells 304 and the second plurality of JFET cells 306 may further include gate contact cross-bars 316 positioned along long edges of each of the first plurality of JFET cells 304. The gate contact cross-bars 316 may connect respective parallel contact strips 310 of the first plurality of JFET cells 304. Thus, in some embodiments, each of the first plurality of JFET cells 304 in JFET device area 302 may contain gate contact area surrounding the channel and source contact area. The gate contact area formed by gate contact strips 310 and gate contact cross-bar 316 may be made of a metal or a silicide, such as nickel-silicide, or any other silicide, metal, or metal alloy suitable for making an ohmic contact with the semiconductor gate region beneath the gate contact area. The gate contact material may have a smaller resistance per unit area than the semiconductor material in gate contact region 211 or gate region 212. For example, the gate contact material may have a resistance per unit area that is smaller than the resistance per unit area of gate contact region 211 or gate region 212 by a factor of 10, 100, 1000, or more. Thus, the difference in the gate resistance between the first plurality of JFET cells 304 in JFET device area 302 and the second plurality of JFET cells 306 in JFET device area 301 may be predominated by the respective presence and absence of gate contact cross-bars 316 in JFET device area 302 and JFET device area 301. Specifically, the inclusion of gate contact cross-bars 316 for the first plurality of JFET cells 304 in JFET device area 302, may provide the first plurality of JFET cells 304 in JFET device area 302 with a smaller gate resistance as compared to the second plurality of JFET cells 306 in JFET device area 301 where such contact cross-bars may be absent. The gate resistance of the second plurality of JFET cells 306 in JFET device area 301 can be further tuned by optimizing cell lengths of the individual cells in a manner similar to the example embodiments in FIG. 2D to reduce turn-off overshoots.

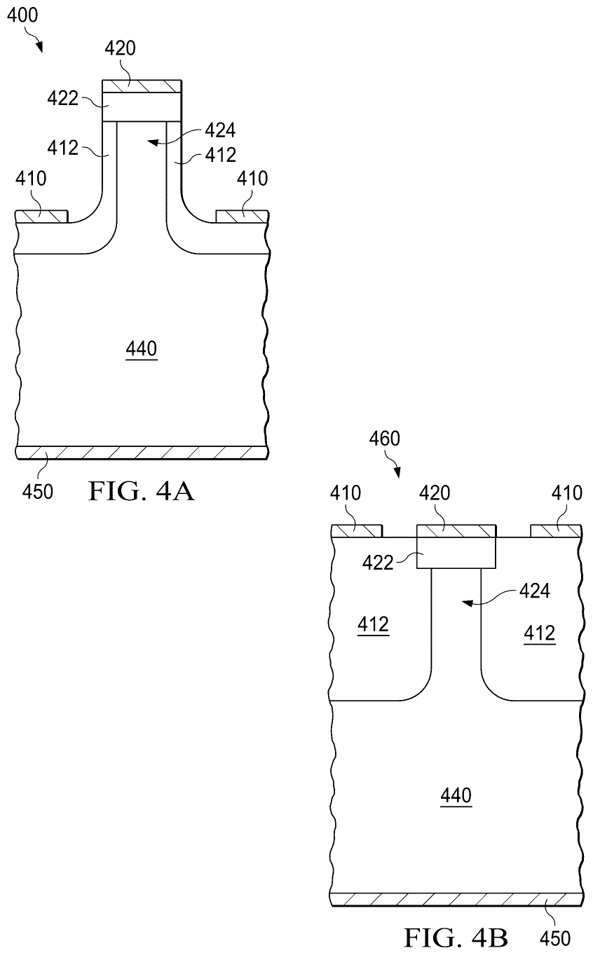

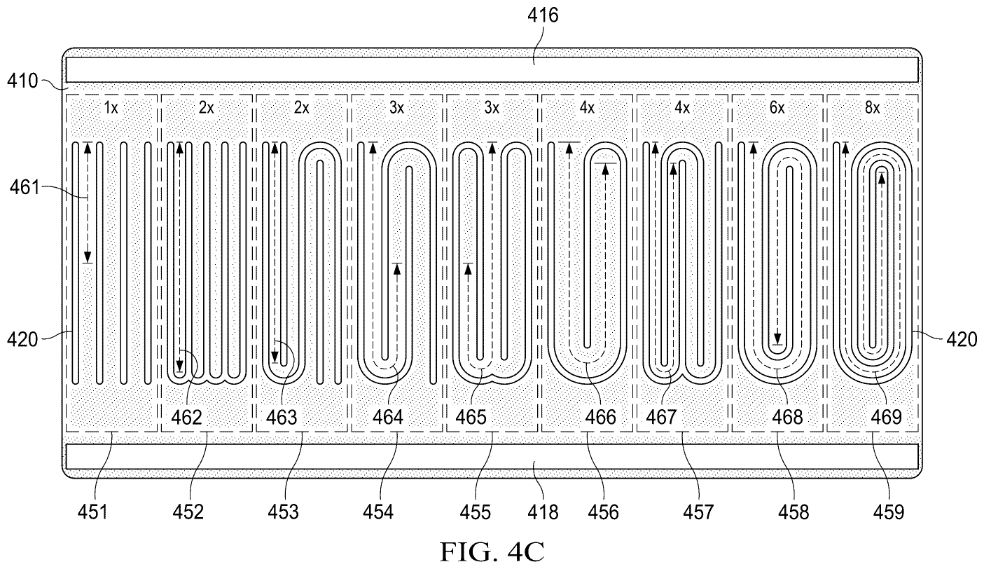

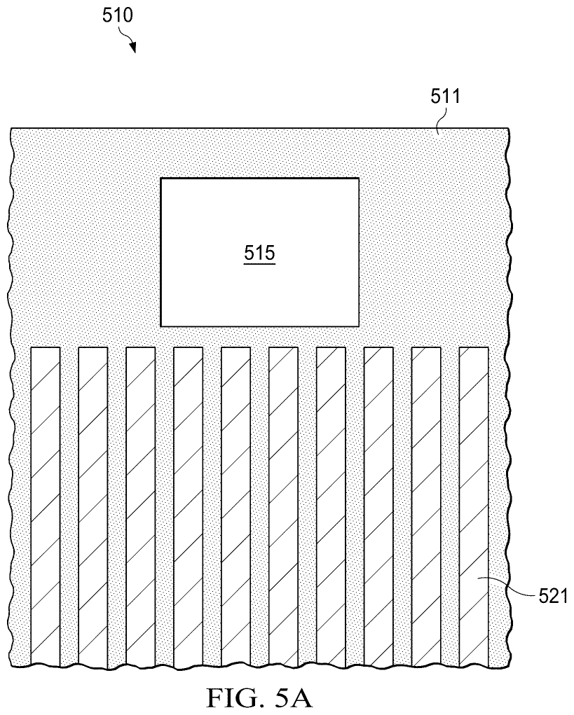

FIG. 4A illustrates a cross-section view of a trench JFET cell 400 in accordance with embodiments of the present disclosure. FIG. 4B illustrates a cross-section view of a planar vertical channel JFET cell 460 in accordance with embodiments of the present disclosure. As shown in FIG. 4A and FIG. 4B, the trench JFET cell 400 and the planar vertical channel JFET cell 460 may both include a vertical channel region 424 that extends vertically between a source region 422 coupled to source contact 420 and a drift region 440 coupled to drain contact 450. And for both the trench JFET cell 400 and the planar vertical channel JFET cell 460, a gate region 412 may extend vertically on the sides of the vertical channel region 424.

In some embodiments, each of source region 422, vertical channel region 424, and drift region 440 may be formed with a first conductivity type, and gate region 412 may be formed with a second conductivity type opposite of first conductivity type. For example, similar to the planar channel JFET cells of FIGS. 2A-2D and 3, in embodiments where source region 422, vertical channel region 424, and drift region 440 are n-type regions, gate region 412 may be a p-type region. And in embodiments where source region 422, vertical channel region 424, and drift region 440 are p-type regions, gate region 412 may be an n-type region. As shown in FIGS. 4A and 4B, the vertical channel region 424 for both the trench JFET cell 400 and the planar vertical channel JFET cell 460 may extend vertically between portions of gate region 412. Accordingly, a voltage potential applied to gate region 412 may serve to pinch vertical channel region 424, thus varying the conductivity of the respective JFET cell from drain to source.

FIG. 4C illustrates a top layout view of JFET cells in accordance with embodiments of the present disclosure. The top layout view of FIG. 4C may apply to both trench JFET cells like in FIG. 4A and planar vertical channel JFET cells like in FIG. 4B. The top layout view of FIG. 4C illustrates the layout of gate contact 410 and source contact 420 for various JFET cell configurations. In some embodiments, the layout of the JFET cells of FIG. 4C may include one or more gate pad contacts (not shown in FIG. 4C) and gate runners 416 and 418 extending, for example, on opposing short sides of each cell. Gate runners 416 and 418 may be formed by a metal, such as aluminum or copper, or a metal alloy, suitable to connect a gate bond pad area to a lower gate contact layer represented by gate contact 410. The material forming gate runners 416 and 418 may have a smaller resistance per unit area than the material forming gate contact 410. For example, material forming gate runners 416 and 418 may have a resistance per unit area that is smaller than the resistance per unit area of the material forming gate contact 410 by a factor of 10, 100, 1000, or more. Accordingly, the total resistance contributed by gate runners 416 and 418, and by gate contact 410, may be predominated by the resistance of gate contact 410.

As shown in FIG. 4C, different JFET cells may have different layout patterns creating different effective lengths of gate contact material between source contacts 420. The effective gate contact length may depend, for example, on the distance along the gate contact between a first end unbounded by source contact 420 and a second end bounded by source contact 420.

For example, JFET cells in area 452 may have an effective gate contact length 462 that is approximately two times longer than the effective gate contact length 461 of the JFET cells in area 451. And JFET cells in area 453 may have an effective gate contact length 463 that is similarly approximately two times longer than the effective gate contact length 461 of the JFET cells in area 451. As a further example, the plurality of JFET cells in area 454 may have an effective gate contact length 464 that is approximately three times longer than the effective gate contact length 461 of the JFET cells in area 451. And JFET cells in area 455 may have an effective gate contact length 465 that is similarly approximately three times longer than the effective gate contact length 461 of the JFET cells in area 451. As shown in FIG. 4C, the JFET cells in area 455 include two parallel paths bounded by source contact 420. Thus, although illustrated as a single length in FIG. 4C, the effective gate contact length 465 may represent the effective gate contact length of both parallel paths.

As yet a further example, the JFET cells in area 456 may have an effective gate contact length 466 that is approximately four times longer than the effective gate contact length 461 of the JFET cells in area 451. And JFET cells in area 457 may have an effective gate contact length 467 that is similarly approximately four times longer than the effective gate contact length 461 of the JFET cells in area 451. As another example, the JFET cells in area 458 may have an effective gate contact length 468 that is approximately six times longer than the effective gate contact length 461 of the JFET cells in area 451. And the JFET cells in area 459 may have an effective gate contact length 469 that is approximately eight times longer than the effective gate contact length 461 of the JFET cells in area 451.

Utilizing a striped cell layout, the total gate resistance of different JFET cells can be tuned by varying the active-area length or the effective cell length of such cells. The contribution of the gate contact layer to the total gate resistance may be proportional to the effective gate contact length for a given cell. Typically, the length of regular striped cells, such as those in area 451, is defined by the active area length and width. But as shown by the examples in areas 452-459, the length of the cells can be increased by connecting several cells in series and/or bounding them by portions of the source contact 420. Accordingly, the patterning of gate contact 410 and source contact 420 may create different JFET cells having different gate resistances. For example, as shown in FIG. 4C, the contribution of gate contact 410 to the total gate resistance for the JFET cells in area 452 and 453 may be twice that of the JFET cells in area 451. As further examples, the contribution of the gate contact 410 to the total gate resistance for the JFET cells in area 454 and 455 may be three times that of the JFET cells in area 451. Moreover, the contribution of gate contact 410 to the total gate resistance for the JFET cells in area 456 and 457 may be four times that of the JFET cells in area 451. Further, the contribution of gate contact 410 to the total gate resistance for the JFET cells in area 458 and 459 may be six and eight times respectively that of the JFET cells in area 451.

In some embodiments, a JFET may be formed by a first and second plurality of JFET cells that may include vertical channel regions (as shown for example in FIGS. 4A and 4B) and that may have a striped cell layout (as shown for example in FIG. 4C). A first plurality of JFET cells may have a first active-area length and the second plurality of JFET cells may have a second active-area length greater than the first active-area length of the first plurality of JFET cells. For example, the first plurality of JFET cells may be arranged in a first striped pattern similar to the JFET cells shown in area 451 of FIG. 4C, while the second plurality of JFET cells may be arranged in a second striped pattern similar to the JFET cells shown in any of areas 452-459 of FIG. 4C. Thus, the second plurality of JFET cells may have a second gate resistance that is greater than a first gate resistance of the first plurality of JFET cells. In some embodiments, the JFET may be a trench JFET with the first and second plurality of JFET cells having cross-sections similar to that of trench JFET cell 400 in FIG. 4A. In other embodiments, the JFET may be a planar vertical channel JFET with the first and second plurality of JFET cells having cross-sections similar to that of planar vertical channel JFET cell 460 in FIG. 4B.

In some embodiments, curved portions of source contact 420 and the underlying portions of source region 422 and vertical channel region 424 may be formed with a narrower width and/or a lower channel doping than for linear portions of source contact 420 and the underlying portions of source region 422 and vertical channel region 424. For example, the second striped pattern of a second plurality of JFET cells, such as the JFET cells shown in any of areas 452-459 of FIG. 4C, may include at least one linear portion having a first source-contact width and at least one curved portion having a second source-contact width that is narrower than the first source-contact width. The curved portion may correspondingly have a second source-region width and a second channel-region width that are respectively less than a first source-region width and a first channel-region width of the linear portion. As another example, the second striped pattern of a second plurality of JFET cells, such as the JFET cells shown in any of areas 452-459 of FIG. 4C, may include at least one linear portion and at least one curved portion, wherein a second channel-region doping of the at least one curved portion may be less than a first channel-region doping of the at least one linear portion. Such narrower widths or lower channel-region doping may ensure that the curved portions of the associated JFET cell are effectively inactive preventing non-uniform turn-on due to a potentially higher threshold voltage than in the linear portions of the associated JFET cell. Any turn-on non-uniformity due to the curved ends of the cell may thus be reduced or eliminated.

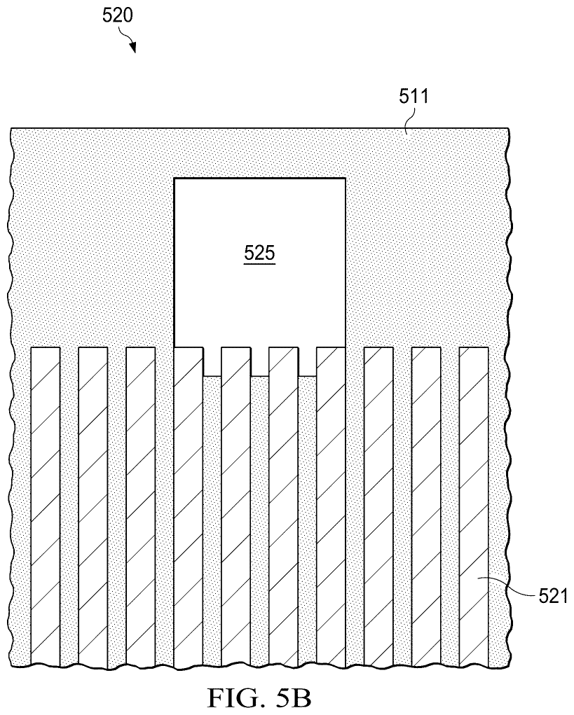

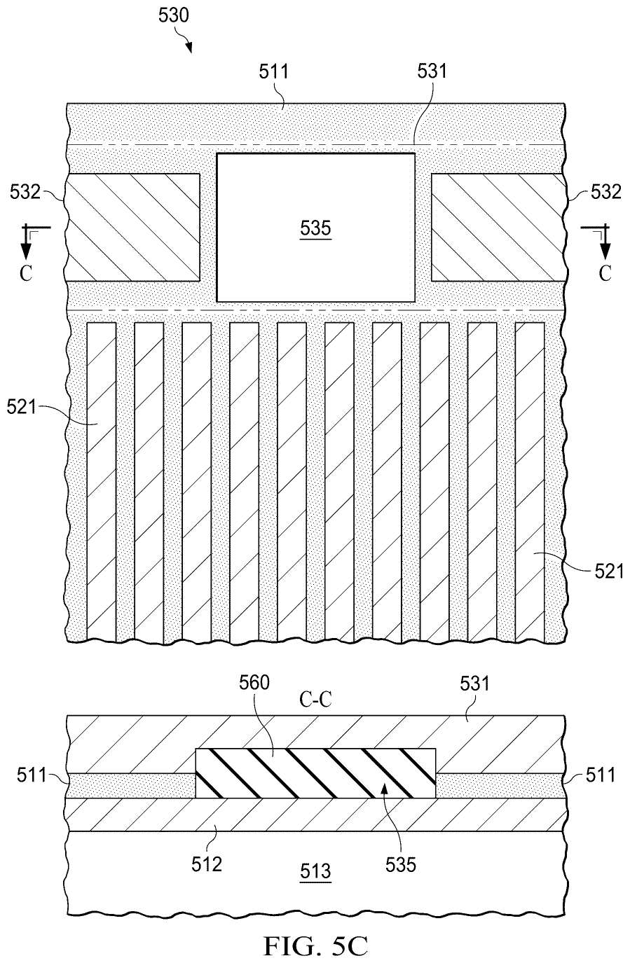

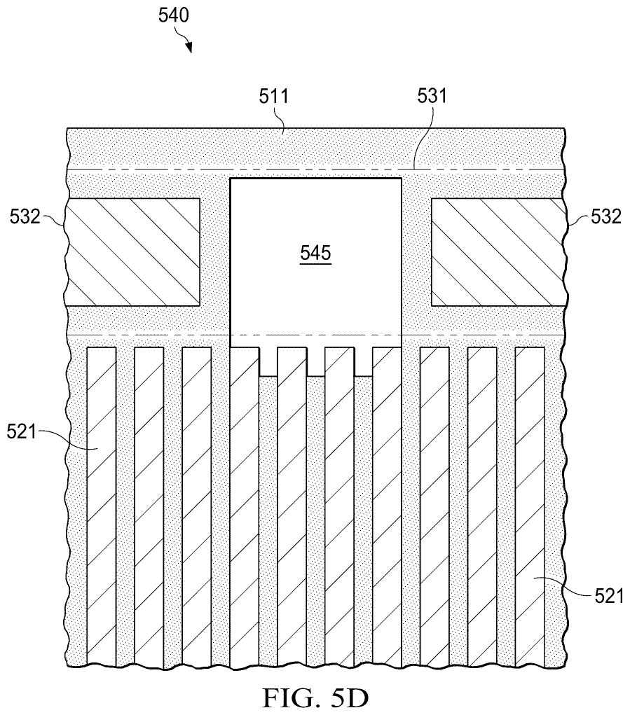

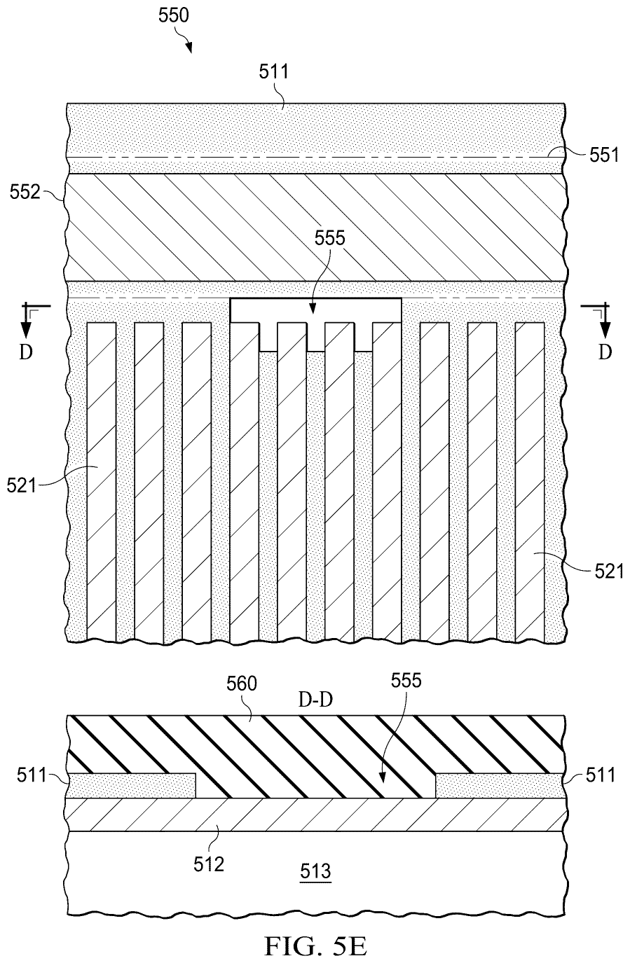

FIGS. 5A-5E illustrate portions of top layout views of multiple JFET cell patterns in accordance with embodiments of the present disclosure. For JFET cell designs including, for example, the lateral, trench, and planar vertical designs described above with reference to FIGS. 2A-2D, 3, and 4A-4C, some portions of the conductive gate contact layer may be omitted to increase the total gate resistance of specific JFET cells relative to other JFET cells. The additional gate resistance may be defined by the dimensions and resistivity of the layer disposed below the removed area of the conductive gate contact layer, for example, the resistivity of the gate region 512 below gate contact 511. Thus, a gate contact layer of the JFET may have one or more cutouts placed such that the gate contact layer contributes a second gate-contact-layer resistance to the second gate resistance of a second plurality of JFET cells that is greater than a first gate-contact-layer resistance contributed by the gate contact layer to a first gate resistance of a first plurality of JFET cells.

For example, as illustrated by area 510 in FIG. 5A, a group of JFET cells may be patterned with gate contact 511 and source contacts 521. Cutout 515 may be located in an area of gate contact 511 adjacent to source contacts 521 of certain JFET cells. Due to the additional gate-contact-layer resistance caused by cutout 515, the JFET cells adjacent to cutout 515 may have a larger total gate resistance than the JFET cells adjacent to a continuous area of gate contact 511. As another example illustrated by area 520 in FIG. 5B, cutout 525 may be partially located in the active area of the device and may, for example, abut and/or be located partially between source contacts 521 of certain JFET cells. Due to the additional gate-contact-layer resistance caused by cutout 525, the JFET cells with source contacts 521 abutting cutout 525 may similarly have a larger gate resistance than the JFET cells adjacent to a continuous area of gate contact 511.

As illustrated in FIG. 5C, some embodiments of the JFET device may include gate runner 531 coupled to gate contact 511 by gate via 532. And as also illustrated in FIG. 5C, cutout 535 may interrupt the continuity of contact between gate runner 531 and gate contact 511. For example, as shown by the cross-section of area 530 along cutline “C-C,” gate contact 511 may be layered above gate region 512 located above substrate 513. The removal or omission of gate contact 511 in the area of cutout 535 may result in an area of gate region 512 that may be exposed to insulator 560 instead of gate contact 511. Due to the additional gate-contact resistance caused by cutout 535, the JFET cells closest to cutout 535 may have a larger total gate resistance than the JFET cells adjacent to a continuous area of gate contact 511.

As another example, illustrated by the JFET cells in area 540 of FIG. 5D, cutout 545 may interrupt the continuity of contact between gate runner 531 and gate contact 511, and may further extend through gate contact 511 to abut the source contacts 521 of certain JFET cells. Due to the additional gate-contact-layer resistance caused by cutout 545, the JFET cells with source contacts 521 abutting cutout 545 may have a larger gate resistance than the JFET cells adjacent to a continuous area of gate contact 511.

As yet another example, illustrated by the JFET cells in area 550 of FIG. 5E, gate runner 551 may be coupled to gate contact 511 by gate via 552. Cutout 555 may be positioned to not interrupt the continuity of contact between gate runner 551 and gate contact 511, but may abut the source contacts 521 of certain JFET cells. For example, as shown by the cross-section of area 550 along cutline “D-D,” gate contact 511 may be layered above gate region 512 located above substrate 513. The removal or omission of gate contact 511 in the area of cutout 555 may result in an area of gate region 512 exposed to insulator 560 instead of gate contact 511. Due to the additional gate-contact-layer resistance caused by cutout 555, the JFET cells with source contacts 521 abutting cutout 555 may have a larger gate resistance than the JFET cells adjacent to a continuous area of gate contact 511.

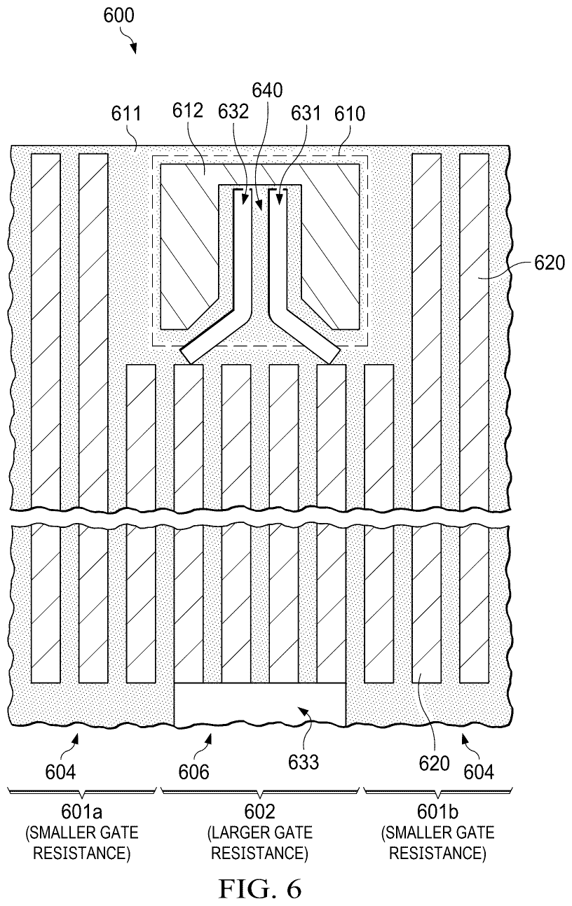

FIG. 6 illustrates a top layout view of JFET 600 including a first plurality of JFET cells 604 and a second plurality of JFET cells 606 in accordance with embodiments of the present disclosure. The first plurality of JFET cells 604 in areas 601a and 601b may collectively represent an embodiment of JFET cell 125a of FIG. 1A having a first gate resistance 124a, while the second plurality of JFET cells 606 in area 602 may collectively represent an embodiment of JFET cell 125b of FIG. 1A having a second gate resistance 124b. In some embodiments, the first plurality of JFET cells 604 and the second plurality of JFET cells 606 may be monolithically formed together on a semiconductor die, for example a semiconductor die with a silicon-carbide (SiC) substrate.

For JFET cell designs including, for example, the lateral, trench, and planar vertical designs described above with reference to FIGS. 2A-2D, 3, and 4A-4C, some portions of the conductive gate contact layer may be omitted to increase the total gate resistance of specific JFET cells relative to other JFET cells. The additional gate resistance may be defined by the dimensions and resistivity of the layer disposed below the removed area of the conductive gate contact layer, for example, the resistivity of the gate region below gate contact 611 shown in FIG. 6. Specifically, similar to the description above for FIGS. 5A-5E, the removal or omission of gate contact 611 in the area of a cutout may result in an area of the gate region that may be exposed to an insulator instead of gate contact 611. And as described above, the material of the gate contact layer, such as gate contact 611, may have a resistance per unit area that is smaller than the resistance per unit area of the underlying gate region by a factor of 10, 100, 1000, or more. Thus, as shown in FIG. 6 and described in greater detail below, gate contact 611 of JFET 600 may have one or more cutouts, such as cutouts 631, 632, and 633, placed such that the gate contact layer contributes a second gate-contact-layer resistance to the second gate resistance of the second plurality of JFET cells 606 that is greater than a first gate-contact-layer resistance contributed by the gate contact layer to the first gate resistance of a first plurality of JFET cells 604.

As shown in FIG. 6, JFET 600 may include JFET cells patterned with gate contact 611 and source contacts 620. JFET 600 may also include gate via 612 within gate pad area 610. Gate via 612 may couple gate contact 611 to a gate pad (not shown in FIG. 6) formed by a metal, such as aluminum, copper, a metal alloy, or any other material suitable for connection to a bond wire.

In some embodiments, some portions of gate contact 611 may be patterned to create a specific gate resistor or plurality of gate resistors. For example, as shown in FIG. 6, cutout 631 and cutout 632 may be patterned within an area of gate contact 611 to create gate resistor 640 out of the gate contact material between cutout 631 and cutout 632. The resistance of gate resistor 640 may depend on the length to width ratio of the area of gate contact 611 between cutout 631 and cutout 632. The length-to-width ratio of gate resistor 640 may be, for example, 10:1, 100:1, 1000:1, or more.

Gate resistor 640 may reside in the gate path of the second plurality of JFET cells 606 in area 602. Further, as shown in FIG. 6, an additional cutout 633 may be located on the opposing side of the second plurality of JFET cells 606 in area 602 and may abut source contacts 620 of the second plurality of JFET cells 606 in area 602. Accordingly, the second plurality of JFET cells 606 in area 602 may have a second gate resistance that is larger than a first gate resistance of a first plurality of JFET cells 604 in areas 601a and 601b. The gate contact material of gate contact 611 may have a resistance per unit area that is smaller than the resistance per unit area of the underlying gate region by a factor of 10, 100, 1000, or more. The dimensions of the cutouts may be defined in a such way that the resistance of the cutout has minimum impact on value of gate resistor 640. For example, the resistance of the cutout parallel to gate resistor 640 may be 10, 50, 100 or more times higher than the resistance of gate resistor 640. Thus, the difference in the gate resistance between the second plurality of JFET cells 606 in area 602 versus the first plurality of JFET cells 604 in areas 601a and 601b may be predominated by the resistance contributed by gate resistor 640.

Although examples have been described above, other modifications and variations or combinations thereof may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

1. A power switch comprising, comprising:
a metal-oxide semiconductor field-effect transistor (MOSFET); and
a junction field effect transistor (JFET) arranged in a cascode configuration with the MOSFET, the JFET comprising:
a first plurality of JFET cells having a first gate resistance; and
a second plurality of JFET cells having a second gate resistance, wherein the second gate resistance is greater than the first gate resistance.

2. The power switch of claim 1, wherein:
the MOSFET is formed on a first die with a silicon substrate;
the JFET is formed on a second die with a silicon-carbide (SiC) substrate; and
the MOSFET and the JFET are co-packaged in a multi-die integrated circuit package.

3. The power switch of claim 1, wherein the first plurality of JFET cells have a first area that is equal to or greater than a second area of the second plurality of JFET cells by a ratio ranging from 1:1 to 20:1.

4. The power switch of claim 1, wherein the second gate resistance of the second plurality of JFET cells is greater than the first gate resistance of the first plurality of JFET cells by a ratio of 10:1 or more.

5. The power switch of claim 1, wherein:
the first plurality of JFET cells and the second plurality of JFET cells include lateral channel regions;
the first plurality of JFET cells each have a first cell length;
the second plurality of JFET cells each have a second cell length; and
the second cell length of the second plurality of JFET cells is greater than the first cell length of the first plurality of JFET cells.

6. The power switch of claim 1, wherein:
the first plurality of JFET cells and the second plurality of JFET cells include lateral channel regions;
wherein the JFET further includes gate contact strips positioned along short edges of each of the first plurality of JFET cells and each of the second plurality of JFET cells; and
wherein the JFET further includes gate contact cross-bars positioned along long edges of each of the first plurality of JFET cells.

7. The power switch of claim 1, wherein:
the first plurality of JFET cells and the second plurality of JFET cells include vertical channel regions with a striped cell layout;
the first plurality of JFET cells have a first active-area length; and
the second plurality of JFET cells have a second active-area length greater than the first active-area length of the first plurality of JFET cells.

8. The power switch of claim 1, wherein a gate contact layer of the JFET has one or more cutouts placed such that the gate contact layer contributes a second gate-contact-layer resistance to the second gate resistance of the second plurality of JFET cells that is greater than a first gate-contact-layer resistance contributed by the gate contact layer to the first gate resistance of the first plurality of JFET cells.

9. The power switch of claim 8, wherein a first cutout and a second cutout of the gate contact layer are patterned to form a gate resistor from gate contact material between the first cutout and the second cutout.

10. The power switch of claim 9, wherein the gate resistor has a length-to-width ratio of 10:1 or more.

11. A junction field effect transistor (JFET) comprising:
a first plurality of JFET cells including lateral channel regions and having a first cell length; and
a second plurality of JFET cells including lateral channel regions and having a second cell length greater than the second cell length of the first plurality of JFET cells; and
wherein the second plurality of JFET cells have a second gate resistance greater than a first gate resistance of the first plurality of JFET cells.

12. The JFET of claim 11, further comprising:
gate contact strips positioned along short edges of each of the first plurality of JFET cells and each of the second plurality of JFET cells; and
gate contact cross-bars positioned along long edges of each of the first plurality of JFET cells.

13. The JFET of claim 11, wherein the first plurality of JFET cells and the second plurality of JFET cells are monolithically formed on a die with a silicon-carbide (SiC) substrate.

14. A junction field effect transistor (JFET) comprising:
a first plurality of JFET cells including vertical channel regions and arranged in a first striped pattern with a first active-area length; and
a second plurality of JFET cells including vertical channel regions and arranged in a second striped pattern having a second active-area length greater than the first active-area length of the first plurality of JFET cells; and
wherein the second plurality of JFET cells have a second gate resistance greater than a first gate resistance of the first plurality of JFET cells.

15. The JFET of claim 14, wherein the JFET is a trench JFET.

16. The JFET of claim 14, wherein the first plurality of JFET cells and the second plurality of JFET cells are monolithically formed on a die with a silicon-carbide (SiC) substrate.

17. The JFET of claim 14, wherein a gate contact layer of the JFET has one or more cutouts placed such that the gate contact layer contributes a second gate-contact-layer resistance to the second gate resistance of the second plurality of JFET cells that is greater than a first gate-contact-layer resistance contributed by the gate contact layer to the first gate resistance of the first plurality of JFET cells.

18. The JFET of claim 17, wherein a first cutout and a second cutout of the gate contact layer are patterned to form a gate resistor from gate contact material between the first cutout and the second cutout.

19. The JFET of claim 14, wherein the second striped pattern of the second plurality of JFET cells includes at least one linear portion having a first source-contact width and at least one curved portion having a second source-contact width that is narrower than the first source-contact width.

20. The JFET of claim 14, wherein:
the second striped pattern of the second plurality of JFET cells includes at least one linear portion and at least one curved portion; and
a second channel-region doping of the at least one curved portion is less than a first channel-region doping of the at least one linear portion.
